(19) United States
(12) Patent Application Publication
(10) Pub. No.: US 2025/0259960 A1
(43) Pub. Date: Aug. 14, 2025

(54) ELECTRONIC MODULE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/052,279

(22) Filed: Feb. 13, 2025

(30) Foreign Application Priority Data
Feb. 14, 2024 (JP) 2024-020371

(51) Int. Cl. H01L 23/00; H01L 23/498

(52) U.S. Cl. CPC H01L 24/32; H01L 23/49811; H01L 23/49833; H01L 2224/26122; H01L 2224/32227

(57) ABSTRACT

An electronic module includes: an electronic element that has an electrode; an internal connection terminal having conductivity that is electrically connected to the electrode of the electronic element; and a spacer that is disposed between the internal connection terminal and the electronic element, wherein a conductive bonding material is disposed between the internal connection terminal and the spacer, and a protruding portion is formed on a surface of the internal connection terminal on an electronic element side, and a distal end of the protruding portion is brought into contact with an upper surface of the spacer.

### CROSS REFERENCE TO RELATED APPLICATIONS

This application claims priority to Japanese Patent Application No. 2024-20371, filed on Feb. 14, 2024, which is expressly incorporated herein by reference in its entirety.

### TECHNICAL FIELD

The present invention relates to an electronic module.

### BACKGROUND ART

Conventionally, there has been known electronic modules each including an electronic element (for example, a chip), a board on which the electronic element is disposed, and a pin terminal that functions as an internal connection terminal connected to a wiring pattern on the board (see a patent literature 1 described hereinafter). Among the electronic modules of this type, there exists an electronic module of a type where an internal connection terminal is connected to an electrode of an electronic element instead of the wiring pattern. As such an electronic module, there has been known an electronic module where an internal connection terminal is connected to an electrode of an electronic element via a spacer having a flat plate shape (for example, a chip spacer). In this case, the spacer and the electrode of the electronic element are bonded to each other by a solder.

### PRIOR ART LITERATURE

### Patent Literature

[Japanese Patent No. 6850938]

### SUMMARY OF INVENTION

### Technical Problem

A spacer (for example, a chip spacer) is used for relaxing a thermal stress of a surface of a chip. However, in a case of a structure where an internal connection terminal is connected to the spacer, a thermal stress is generated in a conductive bonding material (solder) between the spacer and the internal connection terminal due to a change in temperature of the outside. Accordingly, a crack is liable to occur in the conductive bonding material (solder) between the spacer and the internal connection terminal thus giving rise to a drawback that there is a possibility of increasing an electric resistance value or deteriorating heat radiation property of the electronic element (for example, a chip). Further, a distal end of the internal connection terminal has a flat shape and hence, there is a possibility that a loose contact occurs between the internal connection terminal and the spacer. The above-mentioned drawbacks are drawbacks that occur in a case where the spacer exists. However, such drawbacks also occur even in a case where a spacer does not exist and, for example, a distal end of an internal connection terminal and an electrode (electricity supply portion) of an electronic element are bonded to each other via a conductive bonding material.

The present invention has been made in view of the above-mentioned circumstances, and it is an object of the present invention to provide an electronic module that can relax a thermal stress in a conductive bonding material disposed between an internal connection terminal and a spacer (electrode) and, at the same time, can prevent the occurrence of a loose contact between the internal connection terminal and the spacer.

### Solution to Problem

An electronic module according to the present invention is an electronic module that includes: an electronic element that has an electrode; an internal connection terminal having conductivity that is electrically connected to the electrode of the electronic element; and a spacer that is disposed between the internal connection terminal and the electronic element, wherein a conductive bonding material is disposed between the internal connection terminal and the spacer, and a protruding portion is formed on a surface of the internal connection terminal on an electronic element side, and a distal end of the protruding portion is brought into contact with an upper surface of the spacer.

### Advantageous Effects of the Present Invention

According to the electronic module of the present invention, the electronic module includes: the electronic element that has the electrode; the internal connection terminal having conductivity that is electrically connected to the electrode of the electronic element; and the spacer that is disposed between the internal connection terminal and the electrode of the electronic element, wherein the conductive bonding material is disposed between the internal connection terminal and the spacer, and the protruding portion is formed on a surface of the internal connection terminal on an electronic element side. With such a configuration, it is possible to relax a thermal stress that acts on the conductive bonding material (for example, a solder) between the internal connection terminal on which a thermal stress is concentrated and the spacer.

Further, the distal end of the protruding portion is brought into contact with the upper surface of the spacer and hence, a contact portion between the distal end of the protruding portion and the upper surface of the spacer becomes a bonding initiation point. Accordingly, the occurrence of a loose contact between the internal connection terminal and the spacer can be suppressed.

### BRIEF DESCRIPTION OF DRAWINGS

FIG. 1 is a perspective view of an external appearance of an electronic module 100 according to an embodiment.

FIG. 2 is a perspective view illustrating an internal structure of the electronic module 100 according to the embodiment.

FIG. 3 is a perspective view illustrating a peripheral structure of an internal connection terminal 134 according to the embodiment.

FIG. 4 is a view illustrating a structure between the internal connection terminal 134 and a spacer 122.

FIG. 5 is a perspective view illustrating the structure of an upper surface of the spacer 122 according to the embodiment.

FIG. 6A and FIG. 6B are views illustrating a structure of the internal connection terminal 134 according to the embodiment. FIG. 6A is a perspective view illustrating a structure of a lower surface of the internal connection terminal 134 in the embodiment. FIG. 6B is a side view of the internal connection terminal 134 according to the embodiment.

FIG. 7A and FIG. 7B are views illustrating a structure of an internal connection terminal 138 according to a modification. FIG. 7A is a perspective view illustrating a structure of a lower surface of the internal connection terminal according to the modification. FIG. 7B is a side view of the internal connection terminal according to the modification.

FIG. 8 is a view illustrating a modification of an electronic module.

### DESCRIPTION OF EMBODIMENTS

Hereinafter, an electronic module according to an embodiment of the present invention is described with reference to drawings. The embodiment described hereinafter is not intended to limit the invention called for in claims. Further, it is not always the case that all of various constitutional elements and combinations of these constitutional elements described in the embodiment are indispensable as means to solve the problems of the present invention.

### Embodiment

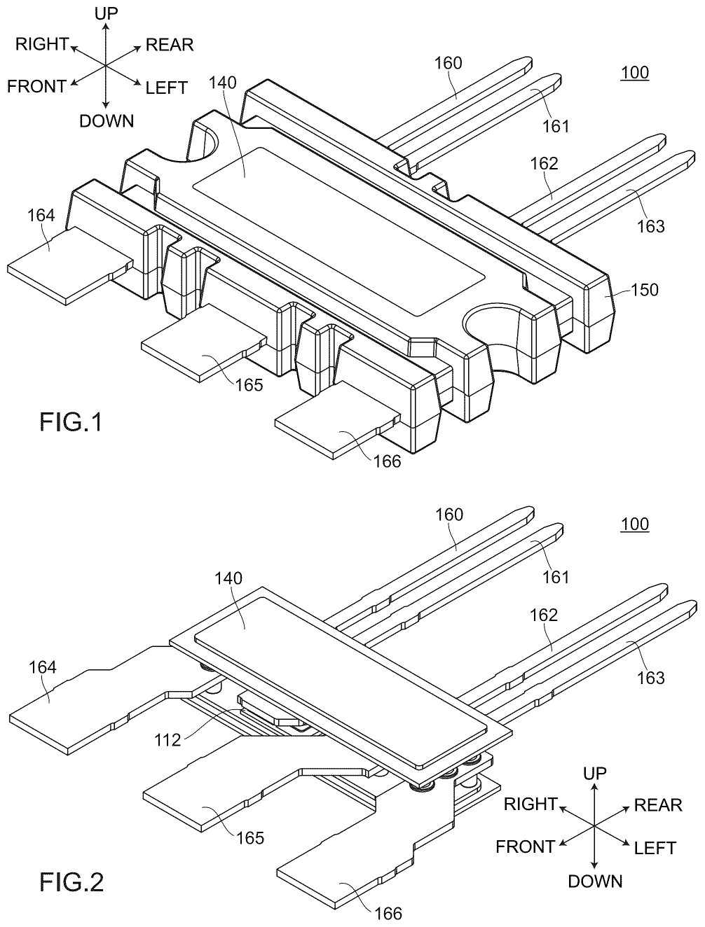

As illustrated in FIG. 1 to FIG. 4, an electronic module 100 according to the embodiment includes a board (first board) 112, an electronic element 120 having an electrode (for example, a source electrode described later) 123, a spacer (chip spacer) 122, an internal connection terminal 134, a board (second board) 140, and lead frames (each constituting an external connection terminal, hereinafter referred to as “external connection terminals”) 160, 161, 162, 163, 164, 165, 166, and a mold resin 150. The external connection terminal 161 is connected to the internal connection terminal 134 at an intermediate position of the internal connection terminal 134. The electronic element (semiconductor element) 120 is bonded to an upper surface of the board 112 via a solder BM3, and an electronic element (semiconductor element: not illustrated in the drawing) is bonded to a lower surface of the board 140.

In the embodiment, the electronic module 100 constitutes a half bridge circuit where the electronic element 120 is used at a high side, and the electronic element bonded to the lower surface of the board 140 is used at a low side. There may be also a case where the electronic element 120 is used at the low side, and the electronic element bonded to a lower surface of the board 140 is used at the high side. The electronic module 100 may include constitutional elements other than the members described above. Hereinafter, for the sake of convenience, the description is made with respect to the constitutional elements in the electronic element 120 of the electronic module 100. The detailed description of the constitutional elements in the electronic element 120 bonded to the lower surface of the board 140 is omitted. In this specification, the expression “electrically connected” may include, besides a case where electricity supply portions of the constitutional elements are directly brought into contact with each other but also a case where the electricity supply portions of the constitutional elements are brought into contact with each other via a different constitutional element having conductivity (for example, a solder or a spacer). The electronic module 100 may have a suitable configuration such as a full bridge circuit other than the half bridge circuit.

The board 112 has a structure where a copper plate is disposed on both surfaces of a ceramic plate (for example, a DCB board). The board 112 is electrically connected with a drain electrode (not illustrated in the drawing) of the electronic element 120. The board 112 is not limited to a DCB board, and may be a printed circuit board or the like, for example.

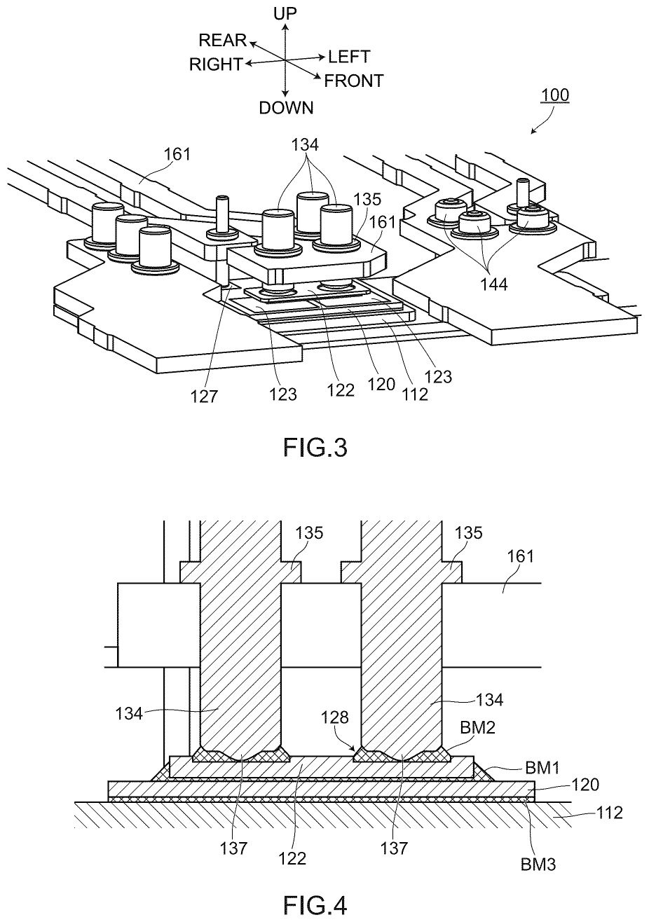

The electronic element 120 is disposed on the board 112. The electronic element 120 is a vertical-type MOSFET that includes: a source electrode 123 disposed on a board 112 side; a drain electrode (not illustrated in the drawing) disposed on a board 112 side; and a gate electrode 127 disposed on the same side as the source electrode 123 (see FIG. 3). The electronic element 120 includes three source electrodes 123 as the source electrodes thereof. The electronic element 120 may be formed of any one of other semiconductor elements such as IGBT, a triac, or a diode. Further, the electronic element 120 may be an electronic element other than the semiconductor element such as a capacitor or an inductor. Further, the number of electronic elements 120 is not limited to two. That is, one electronic element 120 may be used or three or more electronic elements 120 may be used.

The internal connection terminal 134 is an approximately columnar member having conductivity (see FIG. 4), and is electrically connected to the electrode (for example, source electrode) 123 of the electronic element 120. The internal connection terminal 134 is connected to a spacer 122 described later that has a flat plate shape and is made of a conductive material via a conductive boding material (for example, a solder) BM2. Further, in the electronic module 100, three internal connection terminals 134 are provided in conformity with a configuration that the electronic element 120 has three source electrodes 123. In this embodiment, the description is made by taking the example where the internal connection terminal is made of an approximately columnar member. However, the internal connection terminal 134 may not be limited to an internal connection terminal having an approximately columnar shape, and may be an internal connection terminal having a flat plate shape, for example. Further, in this embodiment, the case is exemplified where a cross-sectional shape of the internal connection terminal is a circular shape. However, the cross-sectional shape of the internal connection terminal is not limited to the circular shape, and the internal connection terminal may have a quadrangular cross-sectional shape or the like.

As illustrated in FIG. 6A and FIG. 6B, on a portion of the internal connection terminal 134 on an electronic element 120 side (a portion on a source electrode 123 side), a tapered portion 136 having a frustoconical shape is formed. A protruding portion 137 having a dome shape is formed on a center portion of the tapered portion 136. A distal end (peak head portion) of the protruding portion 137 and the spacer 122 are brought into contact with each other. A conductive bonding material (for example, a solder) BM2 is disposed between portions other than a distal end of the protruding portion 137 and the spacer 122 thus bonding the internal connection terminal 134 and the spacer 122 to each other. The distal end of the protruding portion 137 and the spacer 122 may be directly brought into contact with each other, or may be brought into contact with each other with a relatively thin conductive bonding material (for example, a solder) interposed therebetween. The solder BM2 is applied from the distal end of the protruding portion 137 of the internal connection terminal 134 to an area in the vicinity of an outer peripheral edge via the tapered portion 136. The expression “an area in the vicinity of an outer peripheral edge” means that the expression also includes a case where the solder BM2 is applied from the distal end of the protruding portion 137 to a middle portion of the tapered portion 136.

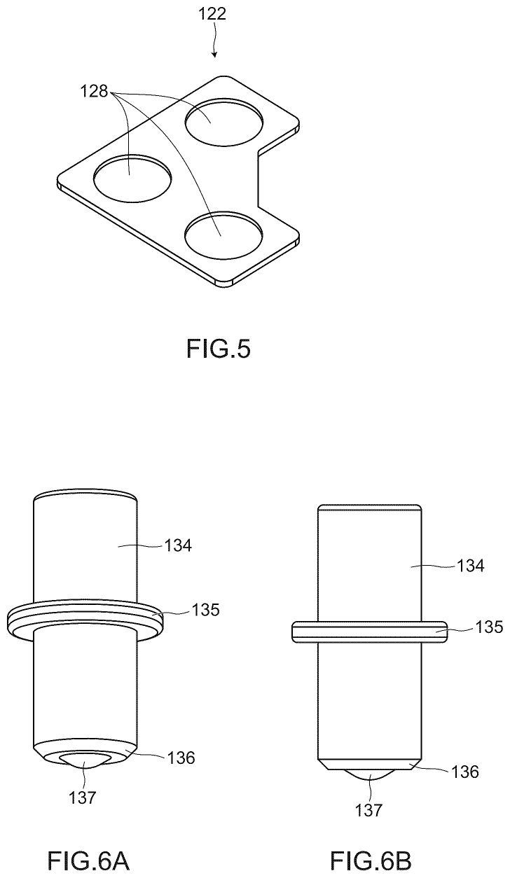

The spacer 122 is disposed between the internal connection terminal 134 and the electronic element 120. As illustrated in FIG. 5, the spacer 122 is a thin flat-plate member having conductivity (in this embodiment, a copper plate), and is formed in a polygonal shape. Three annular indentations (recessed portions) 128 each having an outer diameter larger than a diameter of the internal connection terminal 134 are formed on an upper surface of the spacer 122. A distal end (a peak head portion) of the protruding portion 137 of the internal connection terminal 134 is brought into contact with the upper surface of the spacer 122 (specifically, such an upper surface corresponding to a bottom surface of the indentation 128) via a conductive bonding material (for example, a solder) BM2 (see FIG. 4). Alternatively, such a distal end of the protruding portion 137 may be directly brought into contact with the upper surface of the spacer 122. The number of indentations 128 are not limited to three. It is desired that the number of indentations 128 is not limited to three, and the number of the indentations 128 is the same as the number of internal connection terminals 134.

An external appearance shape of the indentation 128 is a shape that corresponds to a cross-sectional shape of the internal connection terminal 134, and an outer diameter and a depth of the indentation 128 can be changed corresponding to the shape of the internal connection terminal 134. A lower surface of the spacer 122 is bonded to an upper surface of the electronic element 120 (to be more specific, the source electrode 123) via a conductive bonding material (for example, a solder BM1). In this embodiment, the description has been made by exemplifying a case where the outer shape of the spacer 122 is a polygonal shape. However, the outer shape of the spacer 122 is not limited to a polygonal shape.

The external connection terminal 161 is a member that is electrically connected with the internal connection terminal 134 between the board 140 and the electronic element 120. At least one end of the external connection terminal 161 protrudes to the outside of the mold resin 150. The external connection terminal 161 in the electronic module 100 is a detection terminal with respect to the source electrode 123 of the electronic element 120.

### Advantageous Effects Acquired by Embodiment

According to the electronic module of the embodiment, the electronic module 100 includes: the electronic element 120 that has the electrode 123; the internal connection terminal 134 having conductivity that is electrically connected to the electrode 123 of the electronic element 120; and the spacer 122 that is disposed between the internal connection terminal 134 and the electrode 123 of the electronic element 120. In the electronic module 100, the conductive bonding material BM2 is disposed between the internal connection terminal 134 and the spacer 122, and the protruding portion 137 is formed on a surface of the internal connection terminal 134 on an electronic element 120 side. With such a configuration, the solder BM2 has a larger solder thickness at a portion of the internal connection terminal 134 in the vicinity of an outer peripheral edge than at a distal end of the protruding portion 137 of the internal connection terminal 134 and hence, it is possible to secure a sufficient solder thickness at the portion of the internal connection terminal 134 in the vicinity of the outer peripheral edge of the internal connection terminal 134 on which a thermal stress is concentrated. As a result, a thermal stress that acts on the solder BM2 that bonds the internal connection terminal 134 and the spacer 122 to each other can be relaxed.

Further, the distal end of the protruding portion 137 is brought into contact with the upper surface of the spacer 122 and hence, a contact portion between the distal end of the protruding portion 137 and the upper surface of the spacer 122 becomes a bonding initiation point. Accordingly, the occurrence of a loose contact between the internal connection terminal 134 and the spacer 122 can be suppressed.

According to the electronic module of the embodiment, the protruding portion 137 is formed at the center portion of the distal end of the internal connection terminal 134 and hence, the protruding portion 137 can be brought into contact with the connection member (the spacer 122 or the electrode 123) disposed below the protruding portion 137 by a point contact. Accordingly, this contact portion becomes the bonding initiation point and hence, the occurrence of the loose contact between the internal connection terminal 134 and the spacer 122 can be prevented with more certainty.

Further, according to the electronic module 100 of the embodiment, the portion of the internal connection terminal 134 on the above-mentioned electronic element 120 side is formed in a tapered shape. With such a configuration, with respect to the solder thickness of the solder BM2 applied from the center of the protruding portion 137 of the internal connection terminal 134 to the outer peripheral edge by way of the tapered portion 136, such a solder thickness becomes larger at the outer peripheral edge side of the internal connection terminal 134 than at the distal end of the protruding portion 137. Accordingly, it is possible to ensure a sufficient solder thickness at the portion of the internal connection terminal 134 in the vicinity of the outer peripheral edge of the spacer 122 on which a thermal stress is concentrated. As a result, a thermal stress that acts on the solder BM2 that bonds the internal connection terminal 134 and the spacer 122 to each other can be relaxed with more certainty.

The present invention has been described based on the above-mentioned embodiments heretofore. However, the present invention is not limited to the above-mentioned embodiment. The present invention can be carried out in various modes without departing from the gist of the present invention. For example, the following modifications are also conceivable.

### Modification of Shape of Distal End of Internal Connection Terminal

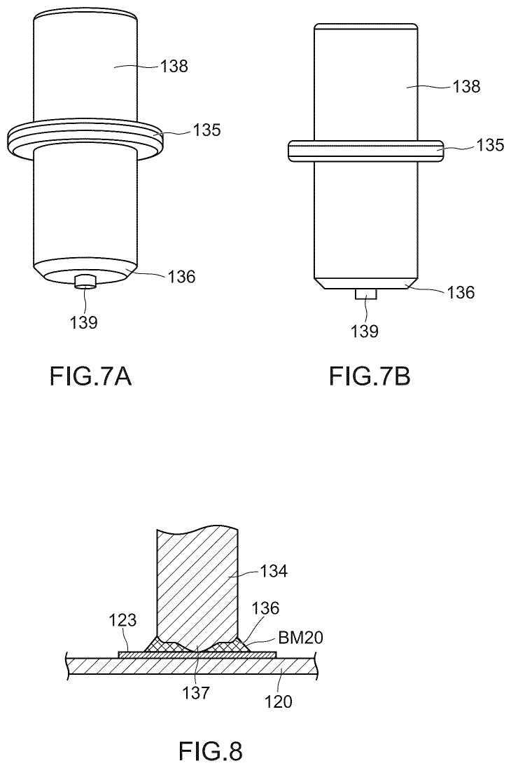

As illustrated in FIG. 7A and FIG. 7B, a distal end of the internal connection terminal 138 is formed in a shape where a protruding portion 139 having a circular columnar shape is formed on a center portion of a lower surface of the tapered portion 136 having a frustoconical shape. In other words, the protruding portion 139 is formed on a center portion of a distal end of the internal connection terminal 138. The distal end of the internal connection terminal 138 is not limited to the above-mentioned distal end shape, and for example, the distal end of the internal connection terminal 138 may have a tapered shape toward the distal end, for example.

### Modification of Electronic Module

In the above-mentioned embodiment, the description has been made with respect to the electronic module where the spacer is disposed between the internal connection terminal and the electronic element.

On other hand, in the modification, although the shape of the internal connection terminal is equal to the shape of the internal connection terminal in the above-mentioned embodiment, the modification differs from the above-mentioned embodiment with respect to a point that the internal connection terminal is connected to the electrode of the electronic element via the conductive bonding material instead of arranging the spacer between the internal connection terminal and the electronic element. Hereinafter, the modification is described with reference to FIG. 8.

The modification has the same configuration as the embodiment other than the point that the internal connection terminal is connected to the electrode of the electronic element via the conductive bonding material without providing the spacer. Accordingly, only portions that make the modification differ from the embodiment are described and the description of the portions having the substantially same configuration is omitted. Further, with respect to symbols indicating the substantially same portions, in a case where it is unnecessary to differentiate the portions of the modification from the corresponding portions of the embodiment, there may be a case where the same symbols are used. The electronic module according to the modification has substantially the same configuration as the electronic module 100 according to the embodiment 1 with respect to points other than the point that the internal connection terminal is connected to the electrode of the electronic element via the conductive bonding material without providing the spacer and hence, the electronic module according to the modification has the corresponding advantageous effects amongst advantageous effects that the electronic module 100 according to the embodiment 1 has.

The protruding portion 137 is formed on a portion of the internal connection terminal 134 on an electronic element 120 side (the portion on a source electrode 123 side). The protruding portion 137 having a dome shape is formed at a center portion of the tapered portion 136. A distal end (peak head portion) of the protruding portion 137 is brought into contact with the source electrode 123 disposed on an upper surface of the electronic element 120 via a conductive bonding material (for example, solder) BM2. Alternatively, the distal end of the protruding portion 137 may be directly brought into contact with the source electrode 123. The electronic module according to the modification has such a configuration and hence, a solder thickness of the solder BM2 applied from the center of the protruding portion 137 to the outer peripheral edge by way of the tapered portion 136 of the internal connection terminal 134 becomes large on an outer peripheral side of the internal connection terminal 134 (see FIG. 4).

Accordingly, a sufficient solder thickness can be secured between the area in the vicinity of an outer peripheral edge of the internal connection terminal 134 and the electrode 123 where a thermal stress is concentrated. As a result, a thermal stress that acts on the solder BM2 that bonds the internal connection terminal 134 and the electrode 123 to each other can be relaxed.

The protruding portion 137 is formed on a distal end side of the internal connection terminal 134 and hence, it is possible to bring the protruding portion 137 into a point contact with the electrode 123 4 the electronic element 120. Accordingly, this contact portion becomes a bonding initiation point and hence, the occurrence of a loose contact between the internal connection terminal 134 and the electrode 123 can be prevented.

According to the electronic module of the modification, the electronic module includes: the electronic element 120 that has the electrode 123 and; the internal connection terminal 134 having conductivity that is electrically connected to the electrode 123 of the electronic element 120, and the conductive bonding material BM2 is disposed between the internal connection terminal 134 and the electrode 123 of the electronic element 120. The protruding portion 137 is formed on the surface of the internal connection terminal 134 on an electronic element 120 side, and the distal end of the protruding portion 137 is brought into contact with the electrode 123 of the electronic element 120. With such a configuration, a solder thickness of the solder BM2 becomes large in the area in the vicinity of the outer peripheral edge of the internal connection terminal 134 compared to the distal end of the protruding portion 137 of the internal connection terminal 134. Accordingly, it is possible to ensure a sufficient solder thickness in the area in the vicinity of the outer peripheral edge of the internal connection terminal 134 to which a thermal stress is concentrated. As a result, a thermal stress that acts on the solder BM2 that bonds the internal connection terminal 134 and the electrode 123 to each other can be relaxed.

Further, the distal end of the protruding portion 137 is brought into contact with the upper surface of the electrode 123 of the electronic element 120 and hence, the contact portion between the distal end of the protruding portion 137 and the upper surface of the electrode 123 becomes a bonding initiation point. Accordingly, the occurrence of a loose contact between the internal connection terminal 134 and the electrode 123 can be suppressed.

Further, according to the electronic module 100 of the embodiment, on the upper surface of the spacer 122, indentation portions 128 each has a shape corresponding to a cross-sectional shape of the internal connection terminal 134 are formed, and the positions where the indentations 128 are formed are disposed at positions corresponding to the positions of the internal connection terminals 134. Accordingly, the indentation portions 128 impart a self-alignment effect to the internal connection terminals 134 that are inserted into the lead frame 161 and hence, the positional displacement of the spacer 122 can be prevented.

1. An electronic module comprising:
an electronic element that has an electrode;
an internal connection terminal having conductivity that is electrically connected to the electrode of the electronic element; and
a spacer that is disposed between the internal connection terminal and the electrode of the electronic element, wherein
a conductive bonding material is disposed between the internal connection terminal and the spacer, and
a protruding portion is formed on a surface of the internal connection terminal on an electronic element side, and a distal end of the protruding portion is brought into contact with an upper surface of the spacer.

2. An electronic module comprising:
an electronic element that has an electrode; and
an internal connection terminal having conductivity that is electrically connected to the electrode of the electronic element, wherein
a conductive bonding material is disposed between the internal connection terminal and the electrode of the electronic element, and
a protruding portion is formed on a surface of the internal connection terminal on an electronic element side, and a distal end of the protruding portion is brought into contact with an electrode of the electronic element.

3. The electronic module according to claim 1, wherein a protruding portion is formed on a center portion of a distal end of the internal connection terminal.

4. The electronic module according to claim 2, wherein a protruding portion is formed on a center portion of a distal end of the internal connection terminal.

5. The electronic module according to claim 1, wherein a portion of the internal connection terminal on an electronic element side has a tapered shape.

6. The electronic module according to claim 2, wherein a portion of the internal connection terminal on an electronic element side has a tapered shape.

7. The electronic module according to claim 1, wherein an indentation having a shape that corresponds to a cross-sectional shape of the internal connection terminal is formed on an upper surface of the spacer, and the indentation is formed at a position that corresponds to a position of the internal connection terminal.
